(19) United States
(12) Patent Application Publication
(10) Pub. No.: US 2014/0151679 A1
(43) Pub. Date: Jun. 5, 2014

(54) METHOD OF FORMING A TOP GATE TRANSISTOR

(71) Applicant: Arne Fleissner, Regensburg (DE)

(72) Inventor: Arne Fleissner, Regensburg (DE)

(73) Assignee: CAMBRIDGE DISPLAY TECHNOLOGY LIMITED, Cambridgeshire (GB)

(21) Appl. No.: 14/234,132

(22) PCT Filed: Jul. 13, 2012
(86) PCT No.: PCT/GB2012/000594

§ 371 Date: Jan. 21, 2014

(30) Foreign Application Priority Data
Jul. 21, 2011 (GB) 1112548.1

(51) Int. Cl. H01L 51/05

(52) U.S. Cl. CPC H01L 51/0508
USPC 257/40; 438/99

(57) ABSTRACT

A method of forming a top-gate transistor over a substrate comprises: forming a source and a drain electrode; forming an organic stack over the source and drain electrodes comprising an organic semiconductor layer and an organic dielectric layer over the organic semiconductor layer; forming a gate bi-layer electrode comprising a first gate layer of a first material and a second gate layer of a different second material; selectively depositing regions of a mask material over the gate bi-layer electrode; performing a first plasma etch step to remove portions of the first gate layer using the mask material as a mask; and performing a second plasma etch step to remove portions of the second gate layer and organic stack using the first gate layer as a mask, thereby patterning the gate bi-layer electrode and the organic stack.

### FIELD OF THE INVENTION

The present invention relates to a method of forming a top-gate transistor over a substrate such as glass or plastic, to a corresponding top-gate transistor, and to display backplanes, biosensors and RFID (radio frequency identification) tags comprising the top-gate transistor.

### BACKGROUND

A thin-film transistor (TFT) is a device formed by depositing an active layer of semiconductor over a separate substrate such as glass or plastic, as opposed to more traditional transistors in which the semiconductor itself forms the substrate of the device. Furthermore, modern TFTs can be formed using organic semiconductors (OSCs) rather than the more traditional inorganic semiconductor materials such as silicon, II-VI semiconductors (e.g., CdSe) or metal oxides (e.g., ZnO). These are referred to as organic thin-film transistors (OTFTs), and have particular advantages over more traditional TFTs. For instance, they have the potential for significantly reduced fabrication costs and scalability to large areas, especially when the OSC is processed from solution. Furthermore, the OSCs are mechanically flexible and can be processed at comparatively lower temperatures that the inorganic semiconductors, so that flexible, but heat-sensitive substrates such as plastic foils, can be used, thus enabling the manufacturing of flexible electronic circuits. Applications in which OTFTs are employed include RFID tags, biosensors, and backplanes for electrophoretic displays. Moreover, OTFTs are of particular interest for use in backplanes for flat panel displays due to the above mentioned advantages, for example for backplanes for organic light-emitting diode (OLED) displays. In this case, the OTFTs have the potential to overcome the limitations of the current standard backplane technologies based on amorphous silicon or poly-crystalline silicon.

An example of a conventional OTFT device is illustrated schematically in FIG. 1. A typical process of producing this device begins by defining source 12 and drain 14 electrodes over the glass substrate 10. An organic stack 20 comprising one or more organic layers is then formed over the substrate 10 and the source and drain electrodes 12, 14. In the example shown, an organic semiconductor layer 20a is first formed over the substrate 10 and the source and drain electrodes 12, 14; next a dielectric layer 20b is formed over the organic semiconductor layer 20a. A gate electrode 30 is then formed over the dielectric layer 20b. This transistor configuration may be referred to as a top-gate transistor.

In operation, charge carriers flow through a channel region between the source and drain electrodes 12, 14 in response to a signal applied to gate electrode 30.

In a conventional top-gate transistor configuration the organic stack 20 is deposited over the entire substrate 10, or at least over substantial areas of the substrate extending well beyond the limits of the source and drain electrodes 12, 14, and then the top-gate electrode is formed by evaporation of a gate metal or metal alloy through a shadow mask. However, in such a conventional configuration, the gate electrode is only coarsely patterned by the shadow mask and typically has lateral dimensions in the order of millimetres, whereas the spacing between the source and drain electrodes (i.e., the length of the active region between the source and the drain electrodes or the so-called transistor channel), is of the order of micrometers. Thus, the gate electrode covers the organic stack not only above the channel region, but also above the source and drain electrodes. The overlap between the gate electrode and the source/drain electrodes leads to undesirable parasitic capacitances. Moreover, the overlap aggravates any gate leakage, i.e., unwanted leakage currents that pass from the source and/or drain electrode through the organic stack to the gate electrode. These effects worsen the performance of the OTFT. Furthermore, a gate electrode of such dimensions is detrimental to integration of OTFTs in electronic circuits and thus impedes, for instance, the use of OTFTs in display backplanes where the pixel size of the display puts severe constraints on the maximum size of the OTFT device.

Recently there has also been interest in the idea of patterning the organic stack 20 to remove semiconductor material which is neither within the transistor channel region nor sandwiched between the conductive gate electrode and the source and/or drain electrodes, in order to prevent the parasitic coupling of neighbouring OTFT devices and to reduce gate leakage. Such a patterning of the organic stack can, for instance, be achieved by using the gate electrode as an etch mask in a dry-etching process. However, the comparatively large dimensions of the gate electrode in a conventional OTFT top-gate configuration limits the beneficial effect of such an approach, because the lateral dimensions of the organic stack after patterning are still much larger than the active channel region.

It would also be beneficial to pattern the gate electrode so that the gate only covers the channel region and has either no overlap with the source and drain electrodes or has a well-defined and well-controlled overlap. This overlap, in contrast to a conventional OTFT configuration, is not of the order of millimetres, but in the order of the dimensions of the channel region or less. Furthermore, it would be beneficial to subsequently pattern the organic stack so that the organic semiconductor material is only present between the gate electrode and the channel region.

However, patterning the top-gate electrode is challenging because care should be taken not to damage the sensitive organic stack lying underneath. This challenge is among those addressed by the present invention.

Commonly known methods for patterning a top-gate electrode and/or an organic layer include high resolution shadow-masking, photolithography, wet etching, and dry etching.

Although evaporation through a high-resolution shadow mask can be used for top-gate patterning in the micrometer range, it is difficult to scale beyond substrates of a few square inches while still maintaining good shadow mask alignment and high gate electrode feature resolution.

Patterning by photolithography involves exposing a layer of light sensitive photoresist material to light through a photomask. The light changes the chemical structure of the photoresist which is exposed through the photomask, so that when a solvent is subsequently applied, the photoresist is developed, i.e. only some portions of the photoresist are removed (either the exposed or unexposed portions depending on whether a positive or a negative photoresist was used). A technique for patterning an organic layer of an OTFT by photolithography is disclosed in U.S. Pat. No. 7,344,928.

Patterning by photolithography can also be used for patterning a metal top-gate electrode by means of a lift-off development process. In this case, the photoresist material is applied on top of an organic stack and a photoresist pattern is created by removing the photoresist from areas in which the gate electrode is required. After blanket evaporating the gate electrode material, the photoresist and any gate electrode material deposited thereupon are lifted off with a suitable solvent developer, so that the gate electrode material would only remain in the required areas. The organic materials in an OTFT tend to be very sensitive to the solvent development process, and unless controlled very carefully, the process is liable to damage the organic stack or simply lift off the whole organic stack rather than only the photoresist. Furthermore, photolithography is an expensive patterning method.

The method of patterning by wet etching involves first blanket depositing the top-gate electrode material onto the organic stack. Subsequently, the method involves forming a patterned mask that would cover the areas of the gate electrode material to be protected during the wet etching, i.e. the areas to form the actual gate electrode. The forming of the patterned mask could be done e.g. by photolithography, in which case a photoresist is patterned and then developed in such a way that the photoresist is removed above the areas of the gate electrode material to be exposed during the wet etching. While this wet-etching method avoids using the above-mentioned lift-off process, the method still involves the development step with its aforementioned associated disadvantages. The gate electrode material which remains exposed by the patterned mask is etched by using a liquid etchant such as an acid, typically by submersing the substrate in a bath of the etchant. However, the organic materials in an OTFT tend to be very sensitive to this kind of liquid etchant, and unless controlled very carefully, the wet etching method is liable to damage or simply lift off the whole organic stack rather than only the desired (exposed) areas of the gate electrode material.

Patterning by dry-etching on the other hand uses a plasma etchant and does not suffer from the above-mentioned drawbacks of patterning by photolithography and by wet-etching. However, dry-etching also requires the formation of a protective etch mask first. If this etch mask is fabricated by e.g. photolithography, the limitations as discussed above apply. One technique for patterning an organic layer of an OTFT by dry etching is disclosed in United States patent application publication number US 2009/0272969 (and its parent application US 2006/216852).

Nonetheless, there remains a limitation to this existing dry-etch patterning technique in that the patterning of the organic material requires an additional wax or grease masking step followed by a subsequent washing step to remove that mask. That is, it requires two separate masking steps for patterning the organic material and then the gate electrode, plus a washing step. These additional steps add an undesirable extra complexity to the fabrication process.

It would therefore be advantageous to find an alternative method for patterning a top-gate electrode (preferably together with an organic stack lying underneath the top-gate electrode) that is based on dry-etching processes and avoids the use of photolithography.

### SUMMARY OF THE INVENTION

According to a first aspect of the present invention, there is provided a method of forming a top-gate transistor over a substrate, the method comprising:

forming a source and a drain electrode over the substrate;

forming an organic stack over the substrate and the source and drain electrodes, the organic stack comprising an organic semiconductor layer over the substrate and the source and drain electrodes and an organic dielectric layer over the organic semiconductor layer ;

forming a gate bi-layer electrode comprising a first layer of a first material and a second layer of a different second material, the first gate layer being formed over the second gate layer, and the second gate layer being formed over the organic stack;

selectively depositing regions of a mask material over the gate bi-layer electrode;

performing a first plasma etch step to remove portions of the first gate layer using the mask material as a mask; and performing a second plasma etch step to remove portions of the second gate layer and organic stack using the first gate layer as a mask, thereby patterning the gate bi-layer electrode and the organic stack.

In the first plasma etch step, only the first, and not the second, gate layer is etched away, the second gate layer remaining substantially intact. Furthermore, the selectively deposited mask material masks against the first plasma etch step such that both the first and second gate layers remain in the gate region. The selectivity of this first plasma etch step may be achieved for example by controlling the time and/or strength of the etch so as to etch only to a certain depth.

The first gate layer is formed of a material having a stronger resistance to the second plasma etch than the second gate layer. Hence, when the second plasma etch step is performed, the already-present first gate layer itself then acts as a mask for the patterning of the second gate layer and the underlying organic stack (as well as resisting etching of the gate bi-layer itself). Thus the gate bi-layer advantageously allows patterning of the gate electrode and the organic stack whilst avoiding the need for wet-etching or expensive photolithography, and also avoiding the need for two separate masking steps for patterning the organic material and then the gate electrode as in US 2009/0272969.

In a particularly preferred embodiment the second plasma etch step further comprises removing the mask material. Because the second plasma etch can be used to remove the remaining mask material in the same step as patterning the gate electrode and the organic stack, this advantageously avoids the need for a separate washing step as in US 2009/0272969.

In a further embodiment, the second gate layer is substantially thicker than the first gate layer.

In another further embodiment the material of the first gate layer is one of aluminium, chromium, nickel and alloys thereof

In yet another further embodiment the material of the first gate layer is one of Al₂O₃, MgO and Sc₂O₃.

In another further embodiment the material of the second gate layer is one of titanium, tungsten, molybdenum, tantalum, niobium and alloys thereof

In a further embodiment the method comprises performing the first plasma etch step by means of an argon plasma sputter etch.

In a further embodiment the method comprises performing the first plasma etch step by means of a chlorine plasma etch.

In a further embodiment the method comprises performing the second plasma etch step by means of an oxygen-fluorine plasma etch.

In yet a further embodiment the mask material comprises an organic mask material.

According to a second aspect of the present invention, there is provided a top gate transistor formed over a substrate, the top-gate transistor comprising:

a source and a drain electrode formed over the substrate;

an organic stack formed over the substrate and the source and drain

electrodes, the organic stack comprising an organic semiconductor layer over the substrate and the source and drain electrodes and an organic dielectric layer over the organic semiconductor layer; and

a gate bi-layer electrode formed over the organic stack comprising a first

layer of a first material and a second layer of a different second material, the first gate layer being formed over the second gate layer, and the second gate layer being formed over the organic stack.

According to a third aspect of the present invention there is provided a backplane for OLED displays comprising the top-gate transistor of the second aspect.

According to a fourth aspect of the present invention there is provided a backplane for flat panel displays comprising the top-gate transistor of the second aspect.

According to a fifth aspect of the present invention there is provided a backplane for electrophoretic displays comprising the top-gate transistor of the second aspect.

According to a sixth aspect of the present invention there is provided a biosensor comprising the top-gate transistor of the second aspect.

According to a seventh aspect of the present invention there is provided an RFID tag comprising the top-gate transistor of the second aspect.

### BRIEF DESCRIPTION OF THE DRAWINGS

For a better understanding of the present invention and to show how it may be put into effect, reference will be made by way of example to the accompanying drawings in which:

FIG. 1 shows a schematic side cross section through the layers of an organic thin-film transistor, and FIGS. 2a to 2f schematically illustrate process steps for forming an organic thin film transistor according to the first aspect of the present invention.

### DETAILED DESCRIPTION OF PREFERRED EMBODIMENTS

The following example employs an ink-jet printed mask material in a two-step metal-bilayer etch process, using only plasma dry-etch steps in order to pattern a metal gate contact on top of a sensitive organic layer stack. Thus it renders photolithography, wet-etching and ink-jet printing of metal inks unnecessary.

The invention allows patterning the top-gate metal contact in an OTFT on top of the sensitive organic layer stack. It maintains the integrity of the organic layers because it employs only dry-etch but no wet-etch steps, thus eliminating the need to immerse the OTFT into an etch liquid, such as an acid or a base. It uses ink-jet printing for patterning the mask material, thus eliminating costly photolithography and enabling scalability to large substrate sizes. It can employ a number of easy-to-ink-jet inks in the ink-jet printing step, thus it renders the difficult task of printing metal inks unnecessary and eliminates the associated annealing step.

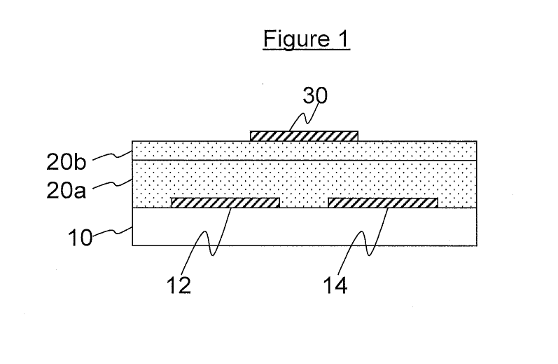

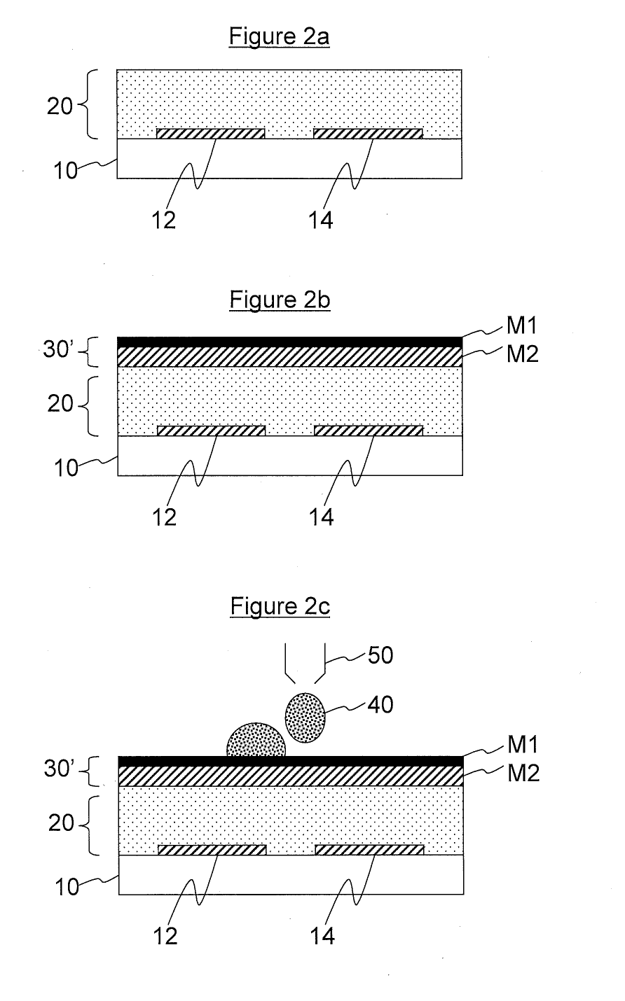

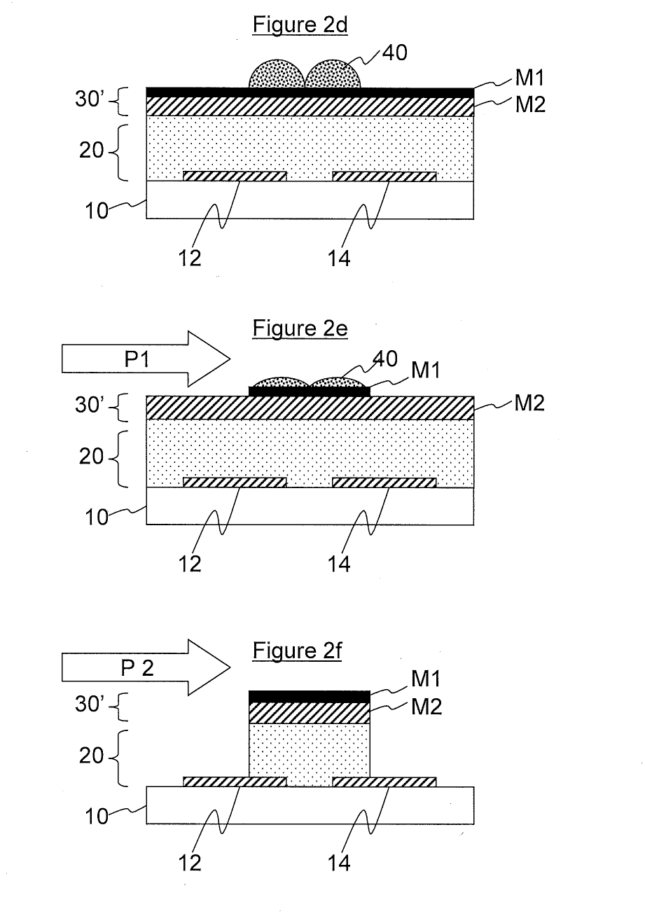

Referring again to FIG. 1, in a conventional top-gate OTFT, the gate electrode 30 is deposited onto the gate dielectric 20b after all the other layers of the transistor structure have been deposited. In OTFTs the fabrication of a metal top-gate 30 is therefore difficult, as it has to be carried out without damaging the organic layer stack 20. The present invention enables fabricating a top-gate metal electrode 30′ whilst avoiding the shortcomings of the existing techniques discussed previously.

An exemplary process will now be described with reference to FIGS. 2a to 2f.

FIG. 2a shows the partially completed OTFT device prior to the top-gate metal deposition. The organic stack 20, that covers the substrate and the source and drain metal electrodes, comprises an organic semiconductor layer and an organic dielectric layer over the organic semiconductor layer (similar to layers 20a and 20b in FIG. 1, but to be subsequently patterned). As will be familiar to a person skilled in the art, in more complex arrangements the organic stack may also comprise additional layers.

The semiconductor used in the organic stack 20 could be any suitable organic semiconductor, examples of which will be familiar to a person skilled in the art. The organic semiconductor can, for example, be a small molecule that is processed by evaporation, including a soluble small molecule that is processed from solution, or a polymer. Examples of small molecules are tetracene, pentacene, and the latter's soluble derivative TIPS Pentacene (6,13-Bis(Triisopropylsilylethynyl) pentacene). Examples of polymer organic semiconductors include P3HT (poly 3-hexylthiophene) and polyfluorene.

The dielectric in the organic stack 20 could be any organic dielectric, examples of which will be familiar to a person skilled in the art. The organic dielectric can be a perfluorinated polymer, PMMA (poly(methyl-methacrylate)) and polystyrene.

The organic stack 20 may be applied by any suitable technique such as spin coating, spray coating, dip coating, slot-die coating, blade coating, drop casting, ink-jet printing, gravure printing, flexographic printing, laser transfer printing, nozzle printing or evaporation.

The source and drain electrodes 12,14 comprise a metal or a metal alloy that is not easily dry-etched by the second plasma step P2 (see below), such as chromium (Cr), which withstands e.g. an oxygen-fluorine plasma. Oxygen-fluorine plasma refers to a plasma which uses oxygen (O₂) and fluorinated hydrocarbon (e.g. CF₄ or CHF₃) as feed gases. The source and drain electrodes 12, 14 may be formed by means of any suitable technique such as photolithography or shadow mask evaporation.

For an efficient OTFT device, the gate electrode 30′ will be formed in a patterned way onto the dielectric layer 20a. A small feature size such as 50 μm or below is preferred for increased OTFT performance and integration in organic electronic circuits, such as display backplanes, RFID tags and biosensors.

As shown in FIG. 2b, a metal bi-layer is blanket-deposited onto the organic stack 20, e.g. by a physical vapour deposition technique or from metal inks In preferred embodiments the metal bi-layer 30′ is deposited by evaporation, such as thermal or sputter evaporation, to avoid the need for metal inks. A layer of a second metal M2 is deposited over the organic stack 20 (over the dielectric 20a), and a layer of a first metal M1 is then deposited on top of the second metal layer M2 (i.e. so the first metal layer M1 is the upper metal layer relative to the lower second metal layer M2).

The second metal M2 is a metal that can easily be plasma dry-etched in the second plasma step P2, e.g. titanium (Ti), which can be dry-etched with an oxygen-fluorine plasma. In contrast, the first metal M1 is a metal that is not easily dry-etched in the second plasma etch step P2 (M1 withstands plasma etch step P2), e.g. aluminium (Al), which withstands an oxygen-fluorine plasma.

Preferably, the first metal layer M1 is thinner than the second metal layer M2, ideally as thin as possible while still retaining the resistance to the second plasma etch step P2. For example, the thickness of Ml could be between 2 nm and 200 nm, preferably between 5 nm and 100 nm, more preferably between 10 nm and 30 nm The thickness of M2, for instance, could be between 20 nm and 500 nm, preferably between 50 nm and 250 nm, more preferably between 75 nm and 150 nm

Turning to FIG. 2c, next an ink jet printer 50 is used to selectively deposit a mask material to form a mask pattern 40 onto the metal bi-layer 30′. The mask material could be an organic ink that is UV-curable, a phase-change (hot-melt) material, or a solvent based material, as long as the resulting layer thickness of the ink-jet printed mask 40 is sufficient to withstand the first plasma etch step P1 (see below). The ink-jet printed mask 40 is shown in FIG. 2d. Various techniques can be used in order to increase resolution and decrease feature size of the ink-jet printed mask. For instance a patterned contrast in wettability on the surface of the first metal layer M1 can be provided, e.g. by employing a photosensitive self-assembled monolayer (SAM) with wetting properties that are photopatternable.

As shown in FIG. 2e, the pattern of the ink-jet printed mask 40 is transferred into the first metal layer M1 by means of a first plasma etch step P1. The result of the first plasma etch step P1 is a selectively removed (i.e. patterned) layer of the first metal M1, as illustrated in FIG. 2e. The first plasma etch step P1 is a plasma dry-etch step capable of etching the first metal layer Ml that is not protected by the printed mask 40 and may be performed by means of an argon plasma sputter etch or a chlorine plasma etch (where the plasma is based on Cl₂/BCl₃ feed gases), which can etch, for example, an aluminium (Al) first metal layer M1.

As mentioned above, the first metal layer M1 is preferably a thin layer, thus minimising the etching time in the first plasma etch step P1. The minimum thickness of the ink-jet printed mask 40 is given by the need for it to withstand the first plasma etch P1 for as long as it takes to etch away the first metal layer M1 in those regions not covered by the mask 40. Using an argon plasma sputter etch is beneficial for this purpose, as it is less selective between metals, such as Al, and organic materials, such as the mask material, than reactive plasmas such as a Cl₂/BCl₃ plasma.

Referring to FIG. 2e to FIG. 2f, the patterned layer of first metal M1 acts as an etch mask in a subsequent plasma etch step P2 during which the uncovered regions of the second metal layer M2 and the organic stack 20 are both plasma-etched. Simultaneously, the remaining organic mask material on top of the patterned layer of first metal M1 is removed by the second plasma etch P2 because an organic mask material is easily dry-etched by an oxygen or oxygen-fluorine plasma. FIG. 2f shows the final patterned top-gate OTFT.

It will be appreciated that the above embodiments have been described only by way of example.

For example, alternative materials of the first gate layer include aluminium (Al), chromium (Cr), nickel (Ni) and metal alloys thereof, which can withstand an oxygen-fluorine plasma. Yet further, the first gate layer could be non-metallic, comprising e.g. oxides such as Al₂O₃, MgO, Sc₂O₃, all of which withstand an oxygen-fluorine plasma. In this case, the first gate layer would not be conductive and only the second gate layer would act as the actual conductive gate electrode material.

Further, alternatives for the material of the second gate layer include titanium (Ti), tungsten (W), molybdenum (Mo), tantalum (Ta), niobium (Nb) or metal alloys thereof, all of which are dry-etchable in an oxygen-fluorine plasma.

The source and drain electrodes may be formed of gold (Au), platinum (Pt), palladium (Pd) and metal alloys thereof.

Further, since the main functionality of the ink-jet printed mask is to form a barrier to plasma etching, almost any kind of organic ink can be used as the mask material provided that the resulting thickness of the mask is sufficient to withstand the first plasma etch step P1 for as long as it takes to etch the first gate layer (e.g. by sputter etching) Thus, even inks that are usually used in everyday graphics printing may be suitable. Some examples for the material to be used as the ink jet printed masks are as follows.

The ink could be an UV-curable ink, e.g. an ink from the SunJet Crystal® range by SunChemical, the Uvijet range by FUJIFILM Sericol, the C-Jet by Collins Ink Corporation, the photoresist SU-8 from Microchem. An example for inkjet printing this latter material is given in the paper Reactive & Functional Polymers 68 (2008) 1052. The ink could also be a hot melt or wax-like ink, e.g. the Spectra® Sabre Hot Melt from Dimatix Fujifilm, or Erucamide, as available for example from Sigma-Aldrich. The ink could also be solvent based, e.g. from the Color+ range by FUJIFILM Sericol, or Polyvinylpyrrolidone, which is soluble in water and other polar solvents, as available for example from Sigma-Aldrich, or Poly-4-vinylphenol, which is soluble in alcohols, ethers, ketones and esters, as available for example from Sigma-Aldrich.

It will also be appreciated that for clarity certain features have been omitted from the described Figures, such as other associated circuitry, protective layers and surface modification layers. Such features will be known to a person skilled in the art.

Other variants may be apparent to a person skilled in the art given the disclosure herein. The scope of the invention is not limited by the described embodiments but only by the appendant claims.

1. A method of forming a top-gate transistor over a substrate, the method comprising:
forming a source and a drain electrode over the substrate;
forming an organic stack over the substrate and the source and drain electrodes, the organic stack comprising an organic semiconductor layer over the substrate and the source and drain electrodes and an organic dielectric layer over the organic semiconductor layer;
forming a gate bi-layer electrode comprising a first gate layer of a first material and a second gate layer of a different second material, the first gate layer being formed over the second gate layer, and the second gate layer being formed over the organic stack;
selectively depositing regions of a mask material over the gate bi-layer electrode;
performing a first plasma etch step to remove portions of the first gate layer using the mask material as a mask; and
performing a second plasma etch step to remove portions of the second gate layer and organic stack using the first gate layer as a mask, thereby patterning the gate bi-layer electrode and the organic stack.

2. The method of claim 1, wherein the second plasma etch step also further comprises removing the mask material.

3. The method of claim 1, wherein the second gate layer is substantially thicker than the first gate layer.

4. (canceled)

5. (canceled)

6. The method of claim 1, wherein the material of the first gate layer is selected from the group consisting of aluminum, chromium, nickel and alloys thereof.

7. The method of claim 1, wherein the material of the first gate layer is one of Al₂O₃, MgO and Sc₂O₃.

8. (canceled)

9. The method of claim 1, wherein the material of the second gate layer is one of titanium, tungsten, molybdenum, tantalum, niobium and alloys thereof.

10. (canceled)

11. The method of claim 1, comprising performing the first plasma etch step by means of an argon plasma sputter etch.

12. The method of claim 1, comprising performing the first plasma etch step by means of a chlorine plasma etch.

13. The method of claim 1, comprising performing the second plasma etch step by means of an oxygen-fluorine plasma etch.

14. The method of claim 1, wherein the mask material comprises an organic mask material.

15. The method of claim 1, comprising selectively depositing regions of the mask material by ink-jet printing.

16. A top-gate transistor formed over a substrate, the top-gate transistor comprising:
a source and a drain electrode formed over the substrate;
an organic stack formed over the substrate and the source and drain electrodes, the organic stack comprising an organic semiconductor layer over the substrate and the source and drain electrodes and an organic dielectric layer over the organic semiconductor layer; and
a gate bi-layer electrode formed over the organic stack comprising a first gate layer of a first material and a second gate layer of a different second material, the first gate layer being formed over the second gate layer, and the second gate layer being formed over the organic stack.

17. The top-gate transistor of claim 16, wherein the second gate layer is substantially thicker than the first gate layer.

18. The top-gate transistor of claim 16, wherein the first gate layer has a thickness of between 2 nm and 200 nm.

19. The top-gate transistor of claim 16, wherein the second gate layer has a thickness of between 20 nm and 500 nm.

20. (canceled)

21. (canceled)

22. The top-gate transistor of claim 16, wherein the material of the first gate layer is aluminum aluminium.

23. (canceled)

24. The top-gate transistor of claim 16, wherein the material of the second gate layer is titanium.

25-29. (canceled)
